(19) United States
(12) Patent Application Publication
(10) Pub. No.: US 2025/0386597 A1
(43) Pub. Date: Dec. 18, 2025

(54) SEMICONDUCTOR DEVICE

(71) Applicant: SAMSUNG ELECTRONICS CO., LTD., Suwon-si (KR)

(72) Inventors: Kyuman HWANG, Suwon-si (KR); Juhun PARK, Suwon-si (KR); Jae Won JEONG, Suwon-si (KR)

(73) Assignee: SAMSUNG ELECTRONICS CO., LTD., Suwon-si (KR)

(21) Appl. No.: 18/984,068

(22) Filed: Dec. 17, 2024

(30) Foreign Application Priority Data
Jun. 13, 2024 (KR) 10-2024-0077246

(51) Int. Cl. H10D 84/85; H10D 84/01

(52) U.S. Cl. CPC H10D 84/856; H10D 84/0167; H10D 84/017; H10D 84/0186; H10D 84/851

(57) ABSTRACT

Provided is a semiconductor device including: a lower active region extending in a first direction and including a lower channel pattern and a lower source/drain pattern on a side of the lower channel pattern; an upper active region spaced apart from the lower channel pattern in a second direction, extending in the first direction, and including an upper channel pattern and an upper source/drain pattern on a side of the upper channel pattern; a gate electrode surrounding the upper and lower channel patterns, and extending in a third direction; a lower source/drain contact below and connected to the lower source/drain pattern; an upper source/drain contact above and connected to the upper source/drain pattern; a vertical via on one side of the upper source/drain pattern and connected to the lower and upper source/drain contacts; and a first dummy structure on another side of the upper source/drain pattern, the first dummy structure including a first dummy pattern extending in the first direction.

### CROSS-REFERENCE TO RELATED APPLICATION

This application is based on and claims priority to Korean Patent Application No. 10-2024-0077246, filed in the Korean Intellectual Property Office on Jun. 13, 2024, the entire contents of which are hereby incorporated by reference.

### BACKGROUND

### 1. Field

The present disclosure relates to a semiconductor device.

### 2. Description of Related Art

A semiconductor device is a core component used to control or amplify an electrical signal in an electronic device, and various types of semiconductor devices may be manufactured. For example, memory devices may be used primarily to store and retrieve data, while non-memory devices may be used to control or amplify electrical signals. The semiconductor device is a core component of an electronic device and plays an important role in various fields including computers, communication equipment, consumer electronics, etc.

With the development of industry, the performance and function requirements of electronic devices are increasing. Accordingly high-performance characteristics of semiconductor devices are desirable, and the integration density of semiconductor devices is increasing to meet these requirements. Various methods for forming semiconductor devices having excellent performance and improved integration density are being studied.

### SUMMARY

Provided is a semiconductor device with improved electrical characteristics and reliability.

According to an aspect of the disclosure, a semiconductor device includes: a lower active region extending in a first direction and including a lower channel pattern and a lower source/drain pattern, wherein the lower source/drain pattern is on at least one side of the lower channel pattern; an upper active region spaced apart from the lower channel pattern in a second direction intersecting the first direction, the upper active region extending in the first direction and including an upper channel pattern and an upper source/drain pattern, wherein the upper source/drain pattern is on at least one side of the upper channel pattern; a gate electrode surrounding the lower channel pattern and the upper channel pattern, and extending in a third direction intersecting each of the first and the second directions; a lower source/drain contact below the lower source/drain pattern and connected to the lower source/drain pattern; an upper source/drain contact above the upper source/drain pattern and connected to the upper source/drain pattern; a vertical via on a first side of the upper source/drain pattern and connected to the lower source/drain contact and the upper source/drain contact; and a first dummy structure on a second side of the upper source/drain pattern, the first dummy structure including a first dummy pattern extending in the first direction.

According to an aspect of the disclosure, a semiconductor device includes: a lower active region extending in a first direction and including a lower channel pattern and a lower source/drain pattern, wherein the lower source/drain pattern is on at least one side of the lower channel pattern; an upper active region spaced apart from the lower channel pattern in a second direction intersecting the first direction, the upper active region extending in the first direction and including an upper channel pattern and an upper source/drain pattern, wherein the upper source/drain pattern is on at least one side of the upper channel pattern; a gate electrode surrounding the lower channel pattern and the upper channel pattern, and extending in a third direction intersecting each of the first and the second directions; a lower source/drain contact below the lower source/drain pattern and connected to the lower source/drain pattern; an upper source/drain contact above the upper source/drain pattern and connected to the upper source/drain pattern; a first dummy structure including a first dummy pattern extending in the first direction and a first dummy pattern liner layer on a side surface of the first dummy pattern; a second dummy structure including a second dummy pattern extending in the first direction and a second dummy pattern liner layer on a side surface of the second dummy pattern; and a vertical via penetrating through at least one of the first dummy pattern and the second dummy pattern in the second direction, wherein the first dummy structure is on a first side of the upper source/drain pattern and the second dummy structure is on a second side of the upper source/drain pattern, wherein the vertical via is connected to the lower source/drain contact and the upper source/drain contact, and wherein a side surface of the vertical via is in contact with at least one of the first dummy pattern liner layer and the second dummy liner layer. According to an aspect of the disclosure, a semiconductor device includes: a lower active region extending in a first direction and including: a plurality of lower channel patterns stacked in a second direction intersecting the first direction; and a lower source/drain pattern on at least one side of the plurality of lower channel patterns; an upper active region spaced apart from the lower active region in the second direction and extending in the first direction, the upper active region including: a plurality of upper channel patterns stacked in the second direction; and an upper source/drain pattern on at least one side of the plurality of upper channel patterns; a gate electrode surrounding the plurality of lower channel patterns and the plurality of upper channel patterns and extending in a third direction intersecting each of the first and the second directions; a lower source/drain contact below the lower source/drain pattern and connected to the lower source/drain pattern; an upper source/drain contact above the upper source/drain pattern and connected to the upper source/drain pattern; a gate contact on the gate electrode and connected to the gate electrode; a vertical via on a first side of the upper source/drain pattern and connected to the lower source/drain contact and the upper source/drain contact; and a dummy structure on a second side of the upper source/drain pattern and including: a dummy pattern extending in the first direction; and a dummy pattern liner layer on a side surface of the dummy pattern, wherein a vertical level of an upper end of the vertical via and a vertical level of an upper surface of the dummy structure is the same, or wherein the vertical level of the upper end of the vertical via is higher than the vertical level of the upper surface of the dummy structure, wherein a vertical level of the upper surface of the dummy structure is lower than a vertical level of an upper surface of the gate electrode, and wherein a first distance between a center line of the upper source/drain pattern and a center line of the dummy structure is the same as a second distance between the center line of the upper source/drain pattern and a center line of the vertical via.

According to one or more example embodiments of the present disclosure, in a semiconductor device having a structure in which the lower active region including the lower channel pattern and the lower source/drain pattern, and the upper active region including the upper channel pattern and the upper source/drain pattern are stacked, the first dummy structure may be on one side of the upper source/drain pattern, the vertical via penetrating the second dummy structure may be on the other side of the upper source/drain pattern, and the vertical via may be formed in a self-aligned manner using the etch selectivity of the dummy pattern and the dummy pattern liner layer of the second dummy structure, so that the difficulty of the manufacturing process of the vertical via can be reduced. Accordingly, a semiconductor device having improved electrical characteristics can be provided.

### BRIEF DESCRIPTION OF THE DRAWINGS

The above and other aspect and features of the present disclosure will be more apparent from the following description taken in conjunction with the accompanying drawings, in which:

FIG. 1 is a plan view provided to explain a semiconductor device according to one or more embodiments;

FIG. 2 is a cross-sectional view taken along line A-A of FIG. 1;

FIG. 3 is a cross-sectional view taken along line B-B of FIG. 1;

FIG. 4 is a cross-sectional view taken along line C-C of FIG. 1;

FIG. 5 is a cross-sectional view taken along line D-D of FIG. 1;

FIG. 6 is an enlarged view provided to explain the semiconductor device with respect to the region R1 of FIG. 3;

FIG. 7 is an enlarged view provided to explain the semiconductor device with respect to the region R2 of FIG. 3;

FIGS. 8 to 10 are enlarged views provided to explain a semiconductor device according to another aspect with respect to the region R2 of FIG. 3;

FIG. 11 is an enlarged view provided to explain a semiconductor device according to yet another aspect with respect to the region R2 of FIG. 3;

FIGS. 12, 13, and 14 are enlarged views provided to explain a semiconductor device according to one or more embodiments with respect to the region R3 of FIG. 3;

FIG. 15 is an enlarged view provided to explain a semiconductor device according to one or more embodiments with respect to the region R3 of FIG. 3; and

FIGS. 16, 17, 18, 19, 20, 21, 22, 23, 24, and 25 are diagrams provided to explain a method for manufacturing a semiconductor device according to one or more embodiments, which illustrate intermediate stages of manufacture.

### DETAILED DESCRIPTION

Hereinafter, exemplary embodiments of the present disclosure are described in detail with reference to the accompanying drawings.

In the following description, like reference numerals refer to like elements throughout the specification.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

Throughout the description, when a member is “on” another member, this includes not only when the member is in contact with the other member, but also when there is another member between the two members.

Herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

With reference to the drawings of a semiconductor device according to one or more embodiments, it is described that the semiconductor device includes a multi-bridge channel field effect transistor (MBCFETTM) including a nanosheet, but the technical essence of the present disclosure is not limited thereto. According to some other aspects, the semiconductor device may include a fin field effect transistor (FinFET), a tunneling FET or a three-dimensional (3D) transistor including a channel region of a fin-type pattern shape. In addition, a semiconductor device according to some other aspects may include a bipolar junction transistor or a laterally-diffused metal-oxide semiconductor (LDMOS) transistor.

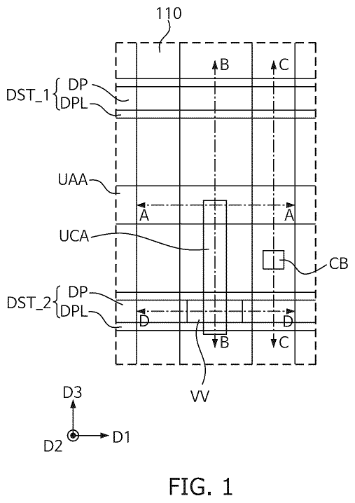

Hereinafter, in the illustrations in FIGS. 1 to 25, a first direction D1, a second direction D2, and a third direction D3 may intersect (e.g., may be perpendicular to) each other, and the combinations of the first direction D1 and the second direction D2, the second direction D2 and the third direction D3, and the first direction D1 and the third direction D3 may each form a plane.

A semiconductor device according to one or more example embodiments will be described with reference to FIGS. 1 to 5.

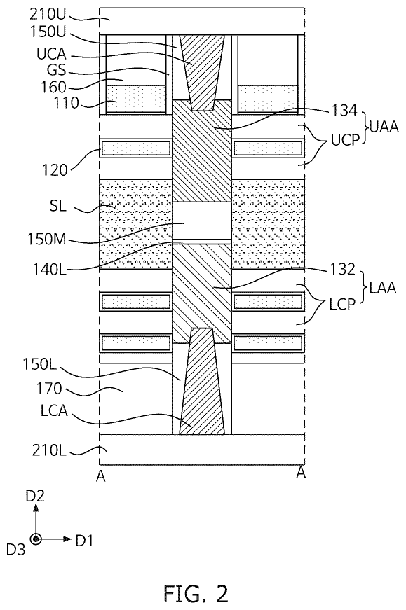

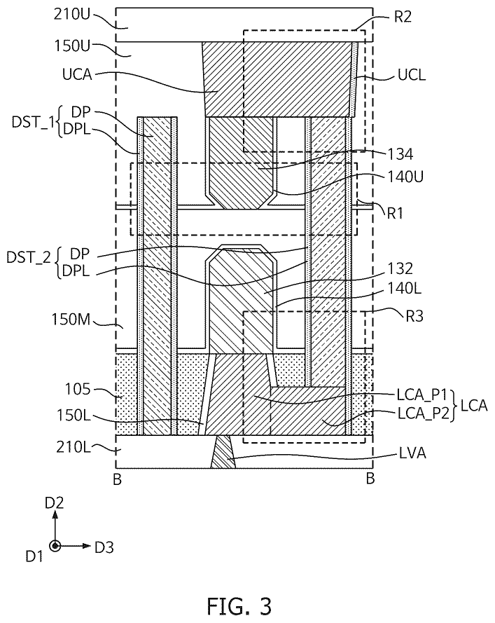

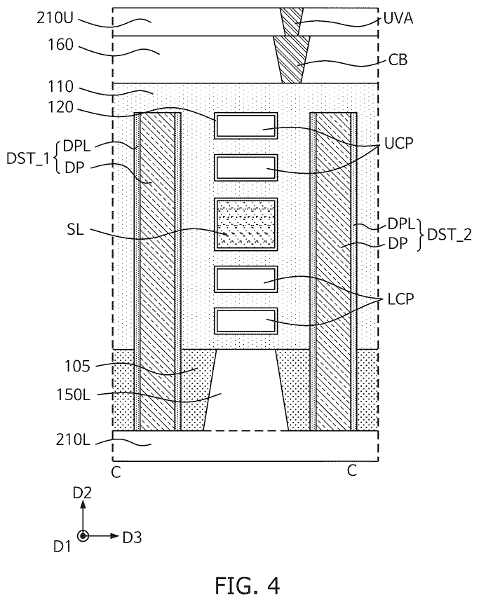

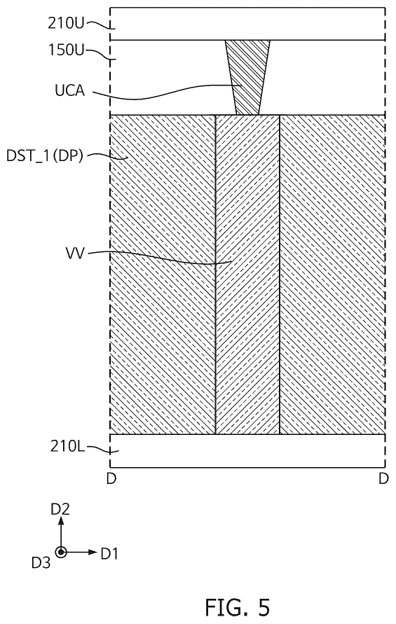

FIG. 1 is a plan view provided to explain the semiconductor device according to one or more example embodiments. FIG. 2 is a cross-sectional view taken along line A-A of FIG. 1. FIG. 3 is a cross-sectional view taken along line B-B of FIG. 1. FIG. 4 is a cross-sectional view taken along line C-C of FIG. 1. FIG. 5 is a cross-sectional view taken along line D-D of FIG. 1.

Referring to FIGS. 1 to 5, the semiconductor device according to one or more example embodiments may include an upper active region UAA, a lower active region LAA, a gate electrode 110, a gate insulating film 120, a gate capping pattern 160, a gate spacer GS, a gate contact CB, a lower gate insulating pattern 170, a lower etching stop film 140L, an upper etching stop film 140U, an intermediate insulating film 150M, an upper insulating film 150U, a lower insulating film 150L, a lower source/drain contact LCA, an upper source/drain contact UCA, a first dummy structure DST_1, a second dummy structure DST_2, a vertical via VV, a lower wiring layer 210L, and an upper wiring layer 210U.

The lower active region LAA may be on the lower gate insulating pattern 170 and the lower insulating film 150L. The lower active region LAA may extend in the first direction D1. The lower active region LAA may include a lower channel pattern LCP and a lower source/drain pattern 132 disposed on at least one side of the lower channel pattern LCP. In one or more example embodiments, the lower channel pattern LCP may include a plurality of sheet patterns. For example, the lower active region LAA may include a plurality of lower channel patterns LCP stacked in the second direction D2, and the lower source/drain pattern 132 disposed on at least one side of the plurality of lower channel patterns LCP.

The upper active region UAA may be disposed on the lower active region LAA. The upper active region UAA may be disposed to be spaced apart from the lower active region LAA in the second direction D2 intersecting the first direction D1. The upper active region UAA may extend in the first direction D1. The upper active region UAA may include an upper channel pattern UCP and an upper source/drain pattern 134 disposed on at least one side of the upper channel pattern UCP. In one or more example embodiments, the upper channel pattern UCP may include a plurality of sheet patterns. For example, the upper active region UAA may include a plurality of upper channel patterns UCP stacked in the second direction D2, and the upper source/drain pattern 134 disposed on at least one side of the plurality of upper channel patterns UCP.

Although it is illustrated that each of the lower channel pattern LCP and the upper channel pattern UCP includes two sheet patterns, the disclosure is not limited thereto. Unlike the illustration, each of the lower channel pattern LCP and the upper channel pattern UCP may include one or three or more sheet patterns. In addition, the number of sheet patterns of the lower channel pattern LCP and the number of sheet patterns of the upper channel pattern UCP may be different from each other. For example, the number of sheet patterns of the lower channel pattern LCP may be 3, and the number of sheet patterns of the upper channel pattern UCP may be 2.

Each of the lower channel pattern LCP and the upper channel pattern UCP may include one of an element semiconductor material such as silicon (Si) or silicon germanium (SiGe), a group IV-IV compound semiconductor, or a group III-V compound semiconductor.

For example, the group IV-IV compound semiconductor may be a binary compound or a ternary compound including at least two or more of carbon (C), silicon (Si), germanium (Ge), tin (Sn), or a compound doped with a group IV element.

For example, the group III-V compound semiconductor may be one of a binary compound, a ternary compound, or a quaternary compound formed by a combination of at least one of aluminum (Al), gallium (Ga), and indium (In) as a group III element and one of phosphorus (P), arsenic (As), and antimony (Sb) as a group V element.

The upper channel pattern UCP may be disposed to be spaced apart from the lower channel pattern LCP in the second direction D2. The upper channel pattern UCP may overlap the lower channel pattern LCP in the second direction D2. A level isolation insulating film SL may be disposed between the upper channel pattern UCP and the lower channel pattern LCP.

The gate electrode 110 may be disposed on the lower active region LAA and the upper active region UAA. The gate electrode 110 may extend in the third direction D3 intersecting each of the first and second directions D1 and D2.

The gate electrode 110 may surround the lower channel pattern LCP and the upper channel pattern UCP. For example, the gate electrode 110 may surround the sheet patterns of the lower channel pattern LCP and the sheet patterns of the upper channel pattern UCP.

The gate electrode 110 may include at least one of a metal, a metal alloy, a conductive metal nitride, a metal silicide, a doped semiconductor material, a conductive metal oxide, and a conductive metal oxynitride. For example, the gate electrode 110 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAlN), tungsten nitride (WN), ruthenium (Ru), titanium aluminum (TiAl), titanium aluminum carbonitride (TiAlCN), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni-Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but is not limited thereto.

It is illustrated that the gate electrode 110 is a single film, but the disclosure is not limited thereto. For example, the gate electrode 110 may include a work function control film that controls a work function and a filling conductive film that fills a space formed by the work function control film. The work function control film may include, for example, at least one of titanium nitride (TiN), tantalum carbide (TaC), tantalum nitride (TaN), titanium aluminum carbide (TiAlC), titanium carbide (TiC), and a combination thereof. The filling conductive film may include, for example, tungsten (W) or aluminum (Al).

The gate insulating film 120 may be disposed on the gate electrode 110. The gate insulating film 120 may be disposed between the gate electrode 110 and the lower channel pattern LCP, between the gate electrode 110 and the upper channel pattern UCP, between the gate electrode 110 and the lower source/drain pattern 132, and between the gate electrode 110 and the upper source/drain pattern 134, respectively. Although the gate insulating film 120 is illustrated as a single film, the disclosure is not limited thereto. Unlike the illustration, the gate insulating film 120 may include a plurality of films. For example, the gate insulating film 120 may include a high-k insulating film and an interfacial insulating film.

The gate insulating film 120 may include, for example, silicon oxide, silicon oxynitride, silicon nitride, or a high-k material having a greater dielectric constant than silicon oxide. For example, the high-k material may include one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

The gate capping pattern 160 may be disposed on an upper surface of the gate electrode 110. The gate capping pattern 160 may cover the upper surface of the gate electrode 110. The gate capping pattern 160 may be disposed between the gate spacers GS. A side surface of the gate capping pattern 160 may be in contact with the gate spacer GS. The upper surface of the gate capping pattern 160 may be disposed coplanar with an upper surface of the upper insulating film 150U. However, the disclosure is not limited thereto.

For example, the gate capping pattern 160 may include at least one of silicon nitride (SiN), silicon oxynitride (SiON), silicon carbon nitride (SiCN), silicon oxycarbonitride (SiOCN), and a combination thereof. The gate capping pattern 160 may include a material having etch selectivity with respect to the upper insulating film 150U.

The gate spacer GS may be disposed on a side surface of the gate electrode 110 and the side surface of the gate capping pattern 160. Specifically, the gate spacer GS may extend along a side surface of a portion of the gate electrode 110, for example, along the side surface of the gate electrode disposed above the uppermost channel pattern, and along the side surface of the gate capping pattern 160.

For example, the gate spacer GS may include at least one of silicon nitride (SiN), silicon nitride oxide (SiON), silicon oxide (SiO₂), silicon carbonate (SiOCN), silicon boron nitride (SiBN), silicon boron oxide (SiOBN), silicon oxycarbide (SiOC), and a combination thereof. Although it is illustrated that the gate spacer GS is a single film, it is only for convenience of explanation, and the disclosure is not limited thereto.

The gate contact CB may be disposed on the gate capping pattern 160. The gate contact CB may penetrate the gate capping pattern 160 in the second direction D2 to be connected to the gate electrode 110. The arrangement of the gate contact CB illustrated in FIG. 4 is an example, and the disclosure is not limited thereto. The gate contact CB may include a conductive material. Although it is illustrated that the gate contact CB is a single film, the disclosure is not limited thereto. Unlike the illustration, the gate contact CB may include a plurality of films.

The lower gate insulating pattern 170 may be disposed on a lower surface of the gate electrode 110. The lower gate insulating pattern 170 may cover the lower surface of the gate electrode 110. The lower surface of the lower gate insulating pattern 170 may be disposed coplanar with a lower surface of the lower insulating film 150L. However, the disclosure is not limited thereto.

For example, the lower gate insulating pattern 170 may include at least one of silicon nitride (SiN), silicon oxynitride (SiON), silicon carbon nitride (SiCN), silicon oxycarbonitride (SiOCN), and a combination thereof.

The lower source/drain pattern 132 may be disposed on at least one side of the lower channel pattern LCP. The lower source/drain pattern 132 may face the lower source/drain pattern adjacent thereto with respect to the lower channel pattern LCP in the first direction D1.

The lower source/drain pattern 132 may include an epitaxial pattern. The lower source/drain pattern 132 may include a semiconductor material. For example, the lower source/drain pattern 132 may include an element semiconductor material such as silicon (Si) or germanium (Ge). In addition, for example, the lower source/drain pattern 132 may include a binary compound or a ternary compound including at least two or more of carbon (C), silicon (Si), germanium (Ge), tin (Sn), or a compound of these doped with a group IV element. For example, the lower source/drain pattern 132 may include silicon (Si), silicon-germanium (SiGe), germanium (Ge), silicon carbide (SiC), etc., but the disclosure is not limited thereto.

The upper source/drain pattern 134 may be disposed to be spaced apart from the lower source/drain pattern 132 in the second direction D2. The upper source/drain pattern 134 may be disposed on at least one side of the upper channel pattern UCP. The upper source/drain pattern 134 may face the upper source/drain pattern adjacent thereto with respect to the upper channel pattern UCP in the first direction D1.

The upper source/drain pattern 134 may include an epitaxial pattern. The upper source/drain pattern 134 may include a semiconductor material. Description of the material of the upper source/drain pattern 134 may be the same as that of the lower source/drain pattern 132.

The lower source/drain pattern 132 and the upper source/drain pattern 134 may have opposite conductivity types. For example, the lower source/drain pattern 132 may have an n-type conductivity, and the upper source/drain pattern 134 may have a p-type conductivity. On the other hand, the lower source/drain pattern 132 may have a p-type conductivity, and the upper source/drain pattern 134 may have an n-type conductivity. In another example, the lower source/drain pattern 132 and the upper source/drain pattern 134 may have the same conductivity type.

The lower etching stop film 140L may be disposed on the lower source/drain pattern 132. The upper etching stop film 140U may be disposed on the upper source/drain pattern 134. For example, each of the lower etching stop film 140L and the upper etching stop film 140U may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbide (SiOC), and a combination thereof.

The intermediate insulating film 150M may be disposed between the lower source/drain pattern 132 and the upper source/drain pattern 134. The intermediate insulating film 150M may cover the lower source/drain pattern 132. For example, the intermediate insulating film 150M may include at least one of silicon oxide (SiO), silicon nitride (SiN), silicon oxynitride (SiON), and a low-k material. For example, the low-k material may include fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), tonen silazen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but is not limited thereto.

The upper insulating film 150U may be disposed on the intermediate insulating film 150M. The upper insulating film 150U may cover the upper source/drain pattern 134. The upper insulating film 150U may surround a sidewall of the gate spacer GS and a sidewall of the gate capping pattern 160. For example, the upper insulating film 150U may include at least one of silicon oxide (SiO), silicon nitride (SiN), silicon oxynitride (SiON), and a low-k material. The low-k material may include the material described above with respect to the intermediate insulating film 150M, and will not be redundantly described below.

The lower insulating film 150L may be disposed below the intermediate insulating film 150M. The lower source/drain pattern 132 may be disposed on an upper surface of the lower insulating film 150L. A field insulating film 105 and the lower gate insulating pattern 170 may be disposed on a side surface of the lower insulating film 150L. For example, the field insulating film 105 may include an oxide, a nitride, a nitride oxide, or a combination thereof. Although it is illustrated that the field insulating film 105 is a single film, it is only for convenience of description, and the disclosure is not limited thereto. For example, the field insulating film 105 may be formed of a plurality of films.

For example, the lower insulating film 150L may include at least one of silicon oxide (SiO), silicon nitride (SiN), silicon oxynitride (SiON), and a low-k material. The low-k material may include the material described above with respect to the intermediate insulating film 150M, and will not be redundantly described below.

The lower source/drain contact LCA may be disposed on a lower surface of the lower source/drain pattern 132. The lower source/drain contact LCA may include a pattern contact part LCA_P1 for contacting the lower source/drain pattern 132, and a connection part LCA_P2 extending in the third direction D3 from the pattern contact part LCA_P1 toward the vertical via VV. The lower source/drain contact LCA may include a conductive material. The lower source/drain contact LCA may be electrically connected to the lower source/drain pattern 132. The lower source/drain contact LCA may penetrate the lower insulating film 150L.

For example, the lower source/drain contact LCA may be disposed on the lower surface of the lower source/drain pattern 132. Although it is illustrated that the lower surface of the lower source/drain pattern 132 and the upper surface of the lower source/drain contact LCA are coplanar, the disclosure is not limited thereto. For example, a portion of the lower source/drain contact LCA may penetrate the lower surface of the lower source/drain pattern 132.

The upper source/drain contact UCA may be disposed on the upper source/drain pattern 134. The upper source/drain contact UCA may include a conductive material. The upper source/drain contact UCA may be electrically connected to the upper source/drain pattern 134. The upper source/drain contact UCA may penetrate the upper insulating film 150U and the upper etching stop film 140U.

For example, the upper source/drain contact UCA may be disposed on an upper surface of the upper source/drain pattern 134. Although it is illustrated that the upper surface of the upper source/drain pattern 134 and a lower surface of the upper source/drain contact UCA are coplanar, the disclosure is not limited thereto. For example, a portion of the upper source/drain contact UCA may penetrate the upper surface of the upper source/drain pattern 134.

The first dummy structure DST_1 may be disposed on one side (e.g., a first side) of the upper source/drain pattern 134. The first dummy structure DST_1 may extend in the first direction D1. In addition, the second dummy structure DST_2 may be disposed on the other side (e.g., a second side opposite the first side) of the upper source/drain pattern 134. The second dummy structure DST_2 may extend in the first direction D1. The first dummy structure DST_1 may face the second dummy structure DST_2 in the third direction D3 with respect to the upper source/drain pattern 134.

An upper end (e.g., an upper surface) of each of the first dummy structure DST_1 and the second dummy structure DST_2 may be positioned on a vertical level lower than that of the upper surface of the gate electrode 110. Each of the first dummy structure DST_1 and the second dummy structure DST_2 may include a region surrounded on an upper surface and side surfaces thereof by the gate electrode 110. For example, a portion of the upper surface and the side surfaces of each of the first dummy structure DST_1 and the second dummy structure DST_2 may be surrounded by the gate electrode 110.

The first dummy structure DST_1 and the second dummy structure DST_2 may include a dummy pattern DP extending in the first direction D1 and a dummy pattern liner layer DPL disposed on a side surface of the dummy pattern DP. The dummy pattern liner layer DPL may extend along the dummy pattern in the first direction D1. The dummy pattern DP may include silicon oxycarbonitride (SiOCN), but the disclosure is not limited thereto. The dummy pattern liner layer DPL may include silicon nitride (SiN), but the disclosure is not limited thereto. The dummy pattern DP may include a material having etch selectivity with respect to the dummy pattern liner layer DPL.

The vertical via VV may be disposed on the other side (e.g., a second side) of the upper source/drain pattern 134. The vertical via VV may penetrate the second dummy structure DST_2 in the second direction D2. A side surface of the vertical via VV may be in contact with the dummy pattern liner layer DPL of the second dummy structure DST_2. The vertical via VV may include a conductive material. The vertical via VV may be electrically connected to the lower source/drain contact LCA and the upper source/drain contact UCA. Although it is illustrated that the vertical via VV penetrates the second dummy structure DST_2, it is for convenience of explanation, and the disclosure is not limited thereto. In one or more example embodiments, the side surface of the vertical via VV may be in contact with the dummy pattern liner layer DPL of at least one of the first dummy structure DST_1 and the second dummy structure DST_2.

In one or more embodiments, the dummy structures are formed on both sides of one source/drain pattern and the vertical via is formed on one of the dummy structures, but this is for illustration only, and a plurality of dummy structures may be disposed between the source/drain patterns, and the vertical vias may be formed on one or more dummy structures according to the design.

An upper boundary liner layer may be disposed between the vertical via VV and the upper source/drain contact UCA. The upper boundary liner layer may include titanium nitride (TiN), but the disclosure is not limited thereto.

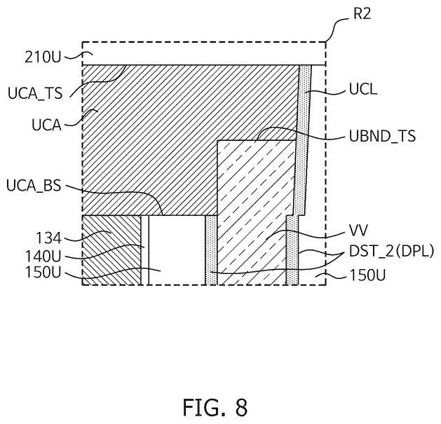

In one or more example embodiments, a boundary surface between the vertical via VV and the upper source/drain contact UCA may be disposed between the upper and lower surfaces of the upper source/drain contact UCA. For example, as illustrated, an upper end of the vertical via VV may have the same vertical level as an upper surface of the first dummy structure DST_1 or may be positioned at a higher vertical level than the upper surface of the first dummy structure DST_1. In addition, the boundary surface between the vertical via VV and the upper source/drain contact UCA, that is, the upper end of the vertical via may have the same vertical level as a bottom surface of the upper source/drain contact. Various aspects of the vertical level of the upper end of the vertical via (e.g., the boundary surface between the vertical via VV and the upper source/drain contact UCA) will be described in detail with reference to FIGS. 8 to 10.

A lower boundary liner layer may be disposed between the vertical via VV and the lower source/drain contact LCA. The lower boundary liner layer may include titanium nitride (TiN), but the disclosure is not limited thereto.

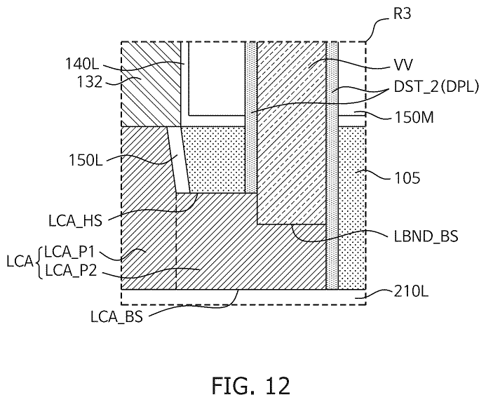

In one or more example embodiments, a boundary surface between the vertical via VV and the lower source/drain contact LCA may be disposed between the upper and lower surfaces of the connection part LCA_P2. For example, as illustrated, the boundary surface between the vertical via VV and the lower source/drain contact LCA, that is, a lower end of the vertical via may have the same vertical level as an upper surface of the connection part LCA_P2. Various aspects of the vertical level of the lower end (e.g., the boundary surface between the vertical via VV and the lower source/drain contact LCA) of the vertical via will be described in detail with reference to FIGS. 12 to 14.

The lower wiring layer 210L may be disposed on the lower surface of the lower insulating film 150L. For example, the lower wiring layer 210L may include at least one of silicon oxide, silicon nitride, silicon oxynitride, and a low-k material. A lower via LVA may be disposed in the lower wiring layer 210L. The lower via LVA may penetrate the lower wiring layer 210L in the second direction D2 to be connected to the lower source/drain contact LCA. The lower via LVA may include a conductive material. Although the lower via LVA is illustrated as being disposed in the lower wiring layer 210L and connected to the lower source/drain contact LCA, this is for illustration only, and the disclosure is not limited thereto. For example, the lower via LVA connected to the lower source/drain contact LCA may be omitted, and an upper via may be disposed in the upper wiring layer 210U to be connected to the upper source/drain contact UCA.

The upper wiring layer 210U may be disposed on the upper surface of the upper insulating film 150U. For example, the upper wiring layer 210U may include at least one of silicon oxide, silicon nitride, silicon oxynitride, and a low-k material. An upper via UVA may be disposed in the upper wiring layer 210U. The upper via UVA may penetrate the upper wiring layer 210U in the second direction D2 to be connected to the gate contact CB. The upper via UVA may include a conductive material.

In a semiconductor device having a structure in which the lower active region including the lower channel pattern and the lower source/drain pattern, and the upper active region including the upper channel pattern and the upper source/drain pattern are stacked, the first dummy structure may be disposed on one side of the upper source/drain pattern, the vertical via penetrating the second dummy structure may be disposed on the other side of the upper source/drain pattern, and the vertical via may be formed in a self-aligned manner according to the etch selectivity of the dummy pattern and the dummy pattern liner layer of the second dummy structure, so that the difficulty of the manufacturing process of the vertical via can be reduced. Accordingly, a semiconductor device having excellent electrical characteristics can be provided.

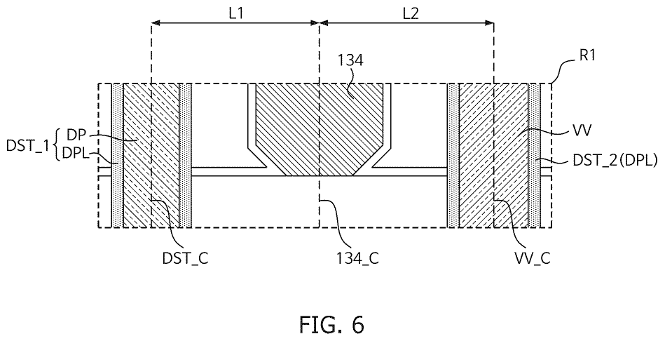

FIG. 6 is an enlarged view provided to explain the semiconductor device with respect to the region R1 of FIG. 3.

In one or more example embodiments, a first distance L1 between a center line 134_C of the upper source/drain pattern 134 and a center line DST_C of the first dummy structure DST_1 may be the same as a second distance L2 between a center line 134 C of the upper source/drain pattern 134 and a center line VV_C of the vertical via VV. In addition, a distance between the center line 134_C of the upper source/drain pattern 134 and the nearest dummy pattern liner of the first dummy structure DST_1 may be the same as a distance between the center line 134_C of the upper source/drain pattern 134 and the nearest dummy pattern liner of the second dummy structure DST_2. Since a plurality of dummy structures are formed between the source/drain patterns, and the vertical via is formed in any of the plurality of dummy structures as required according to design of the semiconductor device, the distance between the dummy structure adjacent to one side of the source/drain pattern and the vertical via adjacent to the other side may be the same.

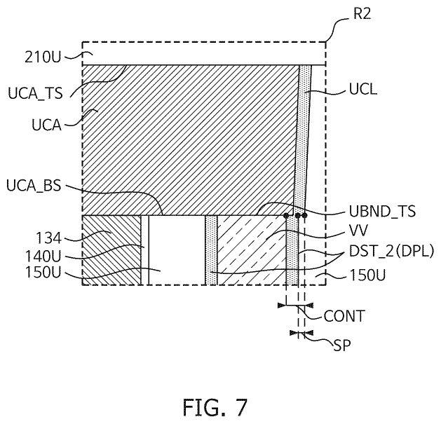

FIG. 7 is an enlarged view provided to explain the semiconductor device with respect to the region R2 of FIG. 3.

In one or more example embodiments, the semiconductor device may further include an upper source/drain contact liner layer UCL disposed along the sidewall of the upper source/drain contact UCA, and a connection region CONT connected with the upper source/drain contact liner layer UCL and the dummy pattern liner layer DPL. For example, the upper source/drain contact liner layer UCL may be connected to the dummy pattern liner layer DPL of the second dummy structure DST_2 disposed on the side surface of the vertical via VV. The upper source/drain contact liner layer UCL may be connected and extend from an upper surface of the dummy pattern liner layer DPL of the second dummy structure DST_2 to the upper wiring layer 210U. For example, the upper source/drain contact liner layer UCL may extend obliquely from a partial region of the upper surface of the dummy pattern liner layer DPL of the second dummy structure DST_2 to the upper wiring layer 210U (e.g., the upper source/drain contact liner layer UCL may extend from a region in which the dummy pattern liner layer DPL overlaps the vertical via VV in the first direction D1). An upper surface of the upper source/drain contact liner layer UCL may be coplanar with a lower surface of the upper wiring layer 210U.

In one or more example embodiments, the connection region CONT may include a step SP formed between the upper source/drain contact liner layer UCL and the dummy pattern liner layer DPL. For example, the upper source/drain contact liner layer UCL and the dummy pattern liner layer DPL may be misaligned in the second direction D2.

FIGS. 8 to 10 are enlarged views provided to explain a semiconductor device according to another aspect with respect to the region R2 of FIG. 3.

Referring to FIGS. 8 to 10, an upper end UBND_TS of the vertical via VV may be disposed between a bottom surface UCA_BS of the upper source/drain contact UCA and an upper surface UCA_TS of the upper source/drain contact UCA. The upper end UBND_TS of the vertical via VV may indicate a region including the uppermost end of the boundary surface between the upper source/drain contact UCA and the vertical via VV.

In one or more example embodiments, the upper end UBND_TS of the vertical via VV may be disposed between the bottom surface UCA_BS of the upper source/drain contact UCA and the upper surface UCA_TS of the upper source/drain contact UCA.

For example, referring to FIG. 8, the upper end UBND_TS of the vertical via VV may be positioned on a vertical level higher than that of the bottom surface UCA_BS of the upper source/drain contact UCA and lower than that of the upper surface UCA_TS of the source/drain contact UCA.

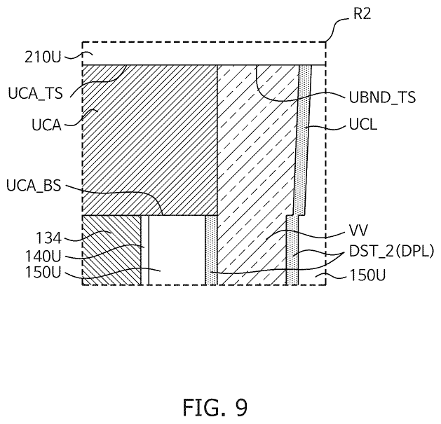

Referring to FIG. 9, the upper end UBND_TS of the vertical via VV may have the same vertical level as that of the upper surface UCA_TS of the upper source/drain contact UCA.

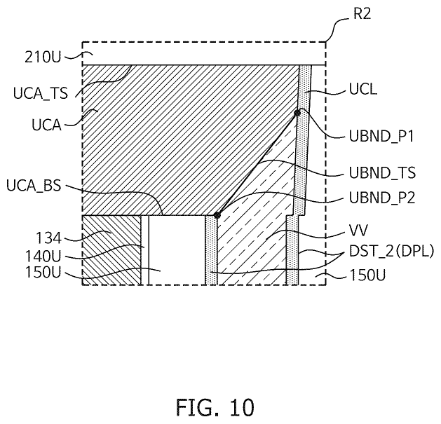

Referring to FIG. 10, the upper end UBND_TS of the vertical via VV may include an inclined surface. The inclined surface of the upper end UBND_TS of the vertical via VV may include one end UBND_P1 and the other end UBND_P2. The one end UBND_P1 may be disposed between the upper surface UCA_TS of the upper source/drain contact UCA and the bottom surface UCA_BS of the upper source/drain contact UCA. The other end UBNS_P2 may be positioned on the same vertical level as that of the bottom surface UCA BS of the upper source/drain contact UCA.

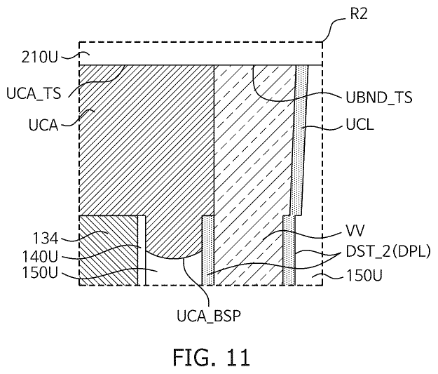

FIG. 11 is an enlarged view provided to explain a semiconductor device according to yet another aspect with respect to the region R2 of FIG. 3.

In one or more example embodiments, a portion UCA_BSP of the bottom surface of the upper source/drain contact UCA may protrude downward. For example, a portion UCA_BSP of the bottom surface of the upper source/drain contact may protrude in the direction of the upper source/drain contact UCA overlapping the lower source/drain contact LCA in the second direction D2.

FIGS. 12 to 14 are enlarged views provided to explain a semiconductor device according to yet another aspect with respect to the region R3 of FIG. 3.

Referring to FIGS. 12 to 14, in one or more example embodiments, the lower source/drain contact LCA may include the pattern contact part LCA_P1 for contacting the lower source/drain pattern 132, and the connection part LCA_P2 extending in the third direction D3 from the pattern contact part LCA_P1 toward the vertical via VV. In this case, a lower end LBND_BS of the vertical via VV may be disposed between an upper surface LCA HS of the connection part LCA_P2 and a bottom surface LCA_BS of the lower source/drain contact LCA. The lower end LBND_BS of the vertical via VV may indicate a region including a lowermost end of a boundary surface between the lower source/drain contact LCA and the vertical via VV.

For example, referring to FIG. 12, the lower end LBND_BS of the vertical via VV may be positioned on a vertical level lower than that of the upper surface LCA_HS of the connection part LCA_P2 and higher than that of the bottom surface LCA BS of the lower source/drain contact LCA.

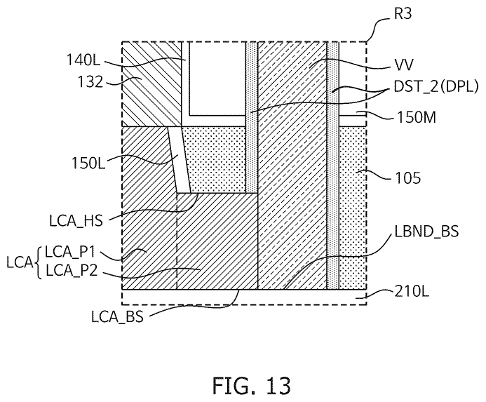

Referring to FIG. 13, the lower end LBND_BS of the vertical via VV may have the same vertical level as that of the bottom surface LCA_BS of the lower source/drain contact

LCA.

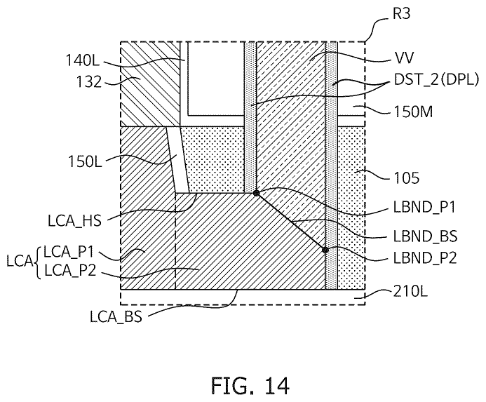

Referring to FIG. 14, the lower end LBND_BS of the vertical via VV may include an inclined surface. The inclined surface of the lower end LBND_BS of the vertical via VV may include one end LBND_P1 and the other end LBND_P2. The one end LBND_P1 of the lower end LBND_BS may be positioned on the same vertical level as that of the upper surface LCA_HS of the connection part LCA_P2. The other end LBND_P2 of the lower end LBND_BS may be disposed between the upper surface LCA_HS of the connection part LCA_P2 and the bottom surface LCA_BS of the lower source/drain contact LCA.

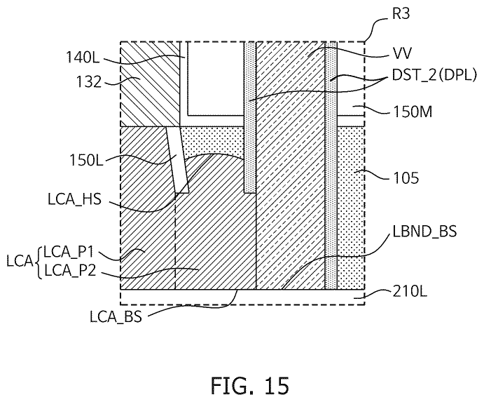

FIG. 15 is an enlarged view provided to explain a semiconductor device according to yet another aspect with respect to the region R3 of FIG. 3.

Referring to FIG. 15, in one or more example embodiments, the upper surface LCA_HS of the connection part LCA_P2 of the lower source/drain contact LCA may protrude upward. For example, the upper surface LCA_HS of the connection part LCA_P2 may protrude in the direction of the upper source/drain contact UCA overlapping the lower source/drain contact LCA in the second direction D2.

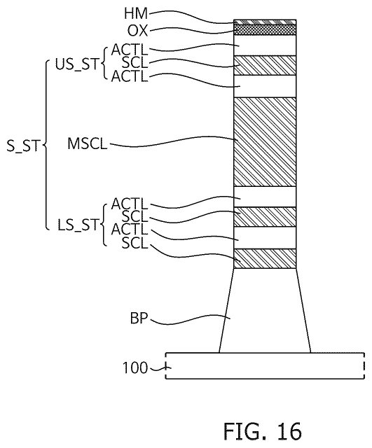

FIGS. 16 to 25 are diagrams provided to explain a method for manufacturing a semiconductor device according to one or more example embodiments, which illustrate intermediate stages of manufacture. For reference, FIGS. 16 to 25 are views corresponding to a cross-sectional view taken along line B-B of FIG. 1.

Referring to FIG. 16, the method for manufacturing the semiconductor device according to one or more example embodiments may include forming a patterned stack structure S_ST on a substrate 100.

The substrate 100 may be a silicon substrate, or may include other materials such as silicon germanium (SiGe), silicon germanium on insulator (SGOI), indium antimony, lead tellurium compound, indium arsenic, indium phosphide, gallium arsenic, or gallium antimony, but is not limited thereto.

The stack structure S_ST may be formed on the substrate 100. The stack structure S_ST may include sacrificial semiconductor layers SC_L and active semiconductor layers ACT_L alternately stacked on top of each other. As illustrated, the stack structure S_ST may include an upper stack structure US_ST, an intermediate sacrificial semiconductor layer MSCL, and a lower stack structure LS_ST. The upper stack structure US_ST may be defined as a stack structure of active semiconductor layers ACT_L and a sacrificial semiconductor layer SC_L disposed above the intermediate sacrificial semiconductor layer MSCL. The lower stack structure BS_ST may be defined as a stack structure of active semiconductor layers ACT_L and a sacrificial semiconductor layer SC_L disposed below the intermediate sacrificial semiconductor layer MSCL. The active semiconductor layer ACT_L and the sacrificial semiconductor layer SC_L may be formed of materials having different etch selectivities.

The stack structure S_ST may be patterned, i.e., selectively removed using sequentially stacked oxide layer OX and hard mask HM. Accordingly, a lower pattern BP may be formed.

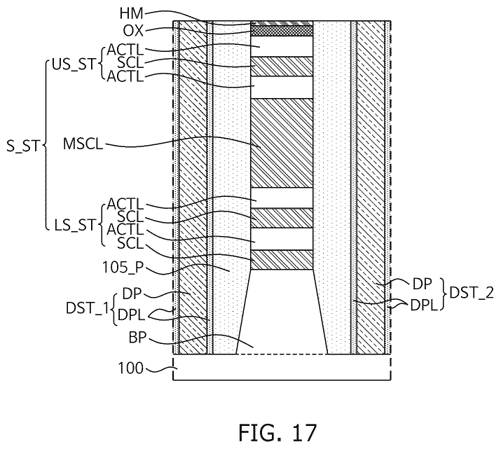

Referring to FIG. 17, a pre-field insulating film 105_P, the dummy pattern liner layer DPL, and a dummy pattern DP may be sequentially formed on a side surface of the stack structure S_ST. For example, by repeating the process of sequentially depositing and etching the pre-field insulating film 105_P, the dummy pattern liner layer DPL, and the dummy pattern DP between the stack structure S_ST and the adjacent stack structure, the dummy pattern DP may be formed on the side surface of the stack structure S_ST, and patterns in which the dummy pattern liner layer DPL and the pre-field insulating film 105_P are sequentially disposed may be formed on both sides of the dummy pattern DP.

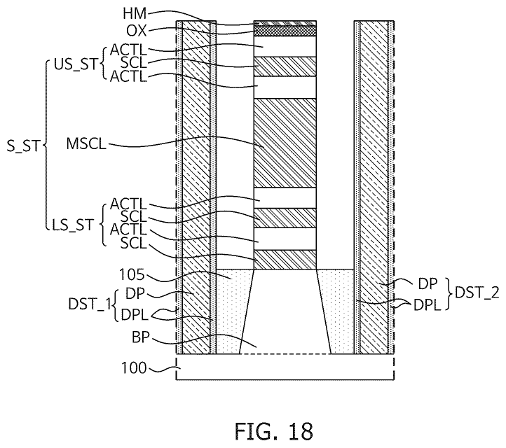

Referring to FIG. 18, the pre-field insulating film 105_P may be patterned to form the field insulating film 105. The field insulating film 105 formed by patterning may extend to an upper surface of the lower pattern BP, but the disclosure is not limited thereto.

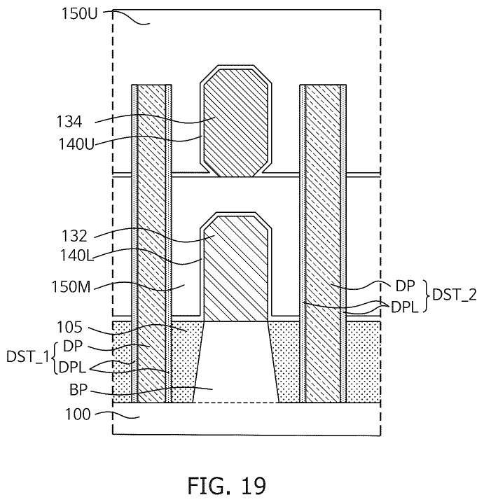

Referring to FIG. 19, the patterned stack structure S_ST may be removed, and the lower source/drain pattern 132, the lower etching stop film 140L, the intermediate insulating film 150M, the upper source/drain pattern 134, the upper etching stop film 140U, and the upper insulating film 150U may be formed.

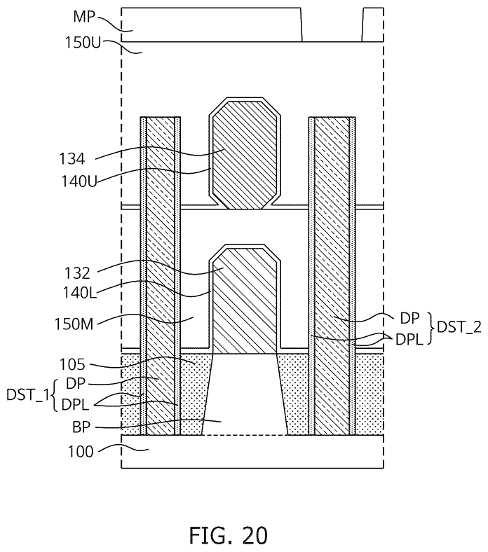

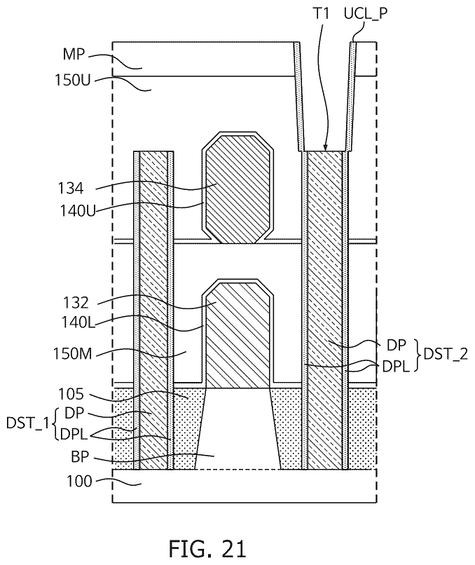

Referring to FIGS. 20 and 21, a mask pattern MP may be formed on the upper surface of the upper insulating film 150U, and an upper source/drain contact trench T1 may be formed using the mask pattern MP as a mask. A pre-upper source/drain contact liner layer UCL_P may be formed on both side surfaces of the upper source/drain contact trench T1.

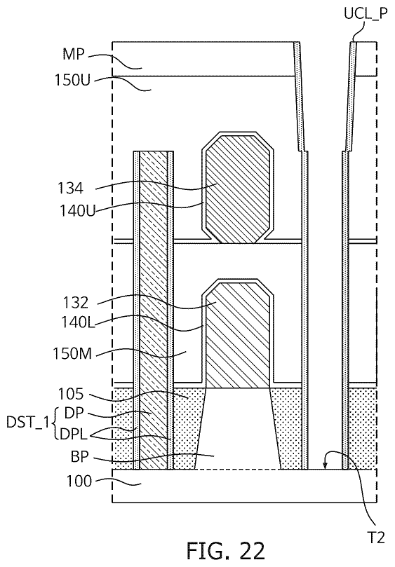

Referring to FIG. 22, a vertical via trench T2 may be formed by removing the dummy pattern DP in a self-aligned manner using the etch selectivity between the dummy pattern liner layer DPL and the dummy pattern DP.

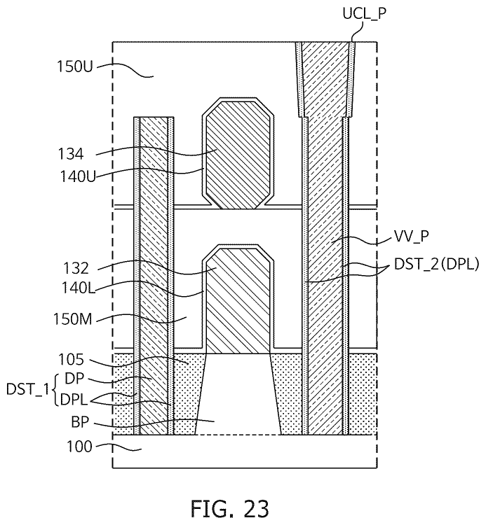

Referring to FIG. 23, a pre-vertical via VV_P may be formed by filling the vertical via trench T2 with a metal material.

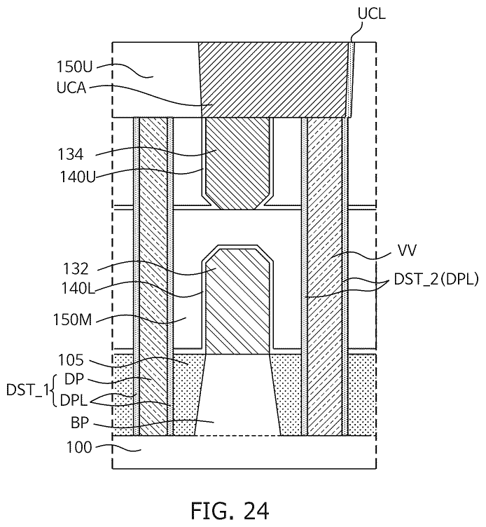

Referring to FIG. 24, the upper source/drain contact UCA may be formed on the upper source/drain pattern 134. The upper source/drain contact UCA may be formed by forming a trench for the upper source/drain contact UCA and filling the same with a metal material. In this case, one of the pre-upper source/drain contact liner layers UCL_P formed on both sides of the upper source/drain contact trench T1 may be removed, and the upper source/drain contact liner layer UCL of the upper source/drain contact trench T1 connected to the dummy pattern liner layer DPL may be formed.

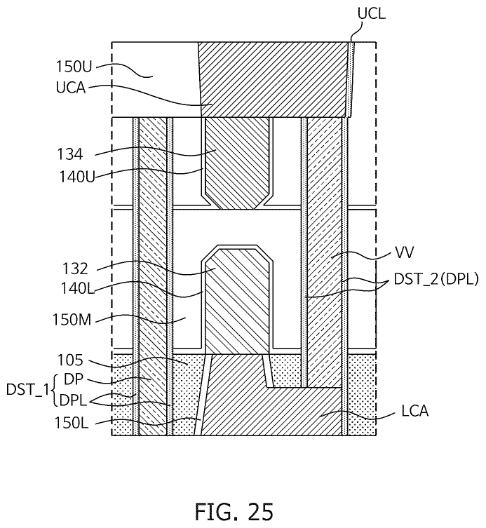

Referring to FIG. 25, the lower source/drain contact LCA may be formed on the lower surface of the lower source/drain pattern 132. By removing the substrate 100, forming the trench for the lower source/drain contact LCA and filling the same with the metal material, the lower source/drain contact LCA can be formed. In this case, the lower pattern disposed below the lower source/drain pattern 132 may be removed and filled with the insulating material so that the lower insulating film 150L may be formed. The lower source/drain contact LCA may be formed by penetrating the lower insulating film 150L. Accordingly, the vertical via VV may be electrically connected to the upper source/drain contact UCA and the lower source/drain contact LCA.

Referring to FIG. 3, the lower wiring layer 210L may be formed below the lower insulating film 150L, and the upper wiring layer 210U may be formed above the upper insulating film 150U.

Although the present disclosure has been described above by way of certain embodiments and drawings, the present disclosure is not limited thereto, and various changes and modifications can be made within the equivalent scope of the technical idea of the present disclosure, and the claims described below, by those of ordinary skill in the art.

What is claimed is:

1. A semiconductor device comprising:
a lower active region extending in a first direction and comprising a lower channel pattern and a lower source/drain pattern, wherein the lower source/drain pattern is on at least one side of the lower channel pattern;
an upper active region spaced apart from the lower channel pattern in a second direction intersecting the first direction, the upper active region extending in the first direction and comprising an upper channel pattern and an upper source/drain pattern, wherein the upper source/drain pattern is on at least one side of the upper channel pattern;
a gate electrode surrounding the lower channel pattern and the upper channel pattern, and extending in a third direction intersecting each of the first and the second directions;
a lower source/drain contact below the lower source/drain pattern and connected to the lower source/drain pattern;
an upper source/drain contact above the upper source/drain pattern and connected to the upper source/drain pattern;
a vertical via on a first side of the upper source/drain pattern and connected to the lower source/drain contact and the upper source/drain contact; and
a first dummy structure on a second side of the upper source/drain pattern, the first dummy structure comprising a first dummy pattern extending in the first direction.

2. The semiconductor device of claim 1,
wherein a vertical level of an upper end of the vertical via and a vertical level of an upper surface of the first dummy structure are the same, or
wherein the vertical level of the upper end of the vertical via is higher than the vertical level of the upper surface of the first dummy structure.

3. The semiconductor device of claim 1, further comprising a second dummy structure on the first side of the upper source/drain pattern,
wherein the vertical via penetrates through the second dummy structure in the second direction.

4. The semiconductor device of claim 1, wherein a first distance between a center line of the upper source/drain pattern and a center line of the first dummy structure is the same as a second distance between the center line of the upper source/drain pattern and a center line of the vertical via.

5. The semiconductor device of claim 1, wherein an upper end of the first dummy structure is on a vertical level lower than a vertical level of an upper surface of the gate electrode.

6. The semiconductor device of claim 1,
wherein the first dummy structure comprises a region, and
wherein an upper surface of the region and a side surface of the region are surrounded by the gate electrode.

7. The semiconductor device of claim 1,
wherein a vertical level of an upper end of the vertical via and a vertical level of a bottom surface of the upper source/drain contact are the same, or
wherein the vertical level of the upper end of the vertical via is higher than of the vertical level of the bottom surface of the upper source/drain contact.

8. The semiconductor device of claim 1,
wherein an upper end of the vertical via comprises an inclined surface,
wherein a first end of the inclined surface of the upper end of the vertical via is between an upper surface of the upper source/drain contact and a bottom surface of the upper source/drain contact, and
wherein a vertical level of a second end of the inclined surface of the upper end of the vertical via and a vertical level of the bottom surface of the upper source/drain contact are the same.

9. The semiconductor device of claim 1, wherein a portion of a bottom surface of the upper source/drain contact protrudes downward.

10. The semiconductor device of claim 1,
wherein the lower source/drain contact comprises a pattern contact part in contact with the lower source/drain pattern, and a connection part extending from the pattern contact part in the third direction toward the vertical via, and
wherein a vertical level of a lower end of the vertical via and a vertical level of an upper surface of the connection part of the lower source/drain contact are the same, or the vertical level of the lower end of the vertical via is lower than the vertical level of the upper surface of the connection part.

11. The semiconductor device of claim 10,
wherein the lower end of the vertical via comprises an inclined surface,
wherein a vertical level of a first end of the inclined surface of the lower end of the vertical via and a vertical level of the upper surface of the connection part of the lower source/drain contact are the same, and
wherein a second end of the inclined surface of the lower end of the vertical via is between the upper surface of the connection part of the lower source/drain contact and a bottom surface of the lower source/drain contact.

12. The semiconductor device of claim 10, wherein the upper surface of the connection part of the lower source/drain contact protrudes upward.

13. The semiconductor device of claim 1,
wherein the first dummy structure further comprises a first dummy pattern liner layer on a side surface of the first dummy pattern, and
wherein the first dummy pattern liner layer extends in the first direction.

14. The semiconductor device of claim 3,
wherein the second dummy structure further comprises a second dummy pattern extending in the first direction and a second dummy pattern liner layer on a side surface of the second dummy pattern,
wherein the second dummy pattern liner layer extends in the first direction, and
wherein a side surface of the vertical via is in contact with the second dummy pattern liner layer.

15. The semiconductor device of claim 14, wherein the semiconductor device further comprises:
an upper source/drain contact liner layer along a sidewall of the upper source/drain contact; and
a connection region connected with the upper source/drain contact liner layer and at least one of the first and the second dummy pattern liner layers.

16. The semiconductor device of claim 15, wherein the connection region comprises a step formed between the upper source/drain contact liner layer and at least one of the first and the second dummy pattern liner layers.

17. A semiconductor device comprising:
a lower active region extending in a first direction and comprising a lower channel pattern and a lower source/drain pattern, wherein the lower source/drain pattern is on at least one side of the lower channel pattern;
an upper active region spaced apart from the lower channel pattern in a second direction intersecting the first direction, the upper active region extending in the first direction and comprising an upper channel pattern and an upper source/drain pattern, wherein the upper source/drain pattern is on at least one side of the upper channel pattern;
a gate electrode surrounding the lower channel pattern and the upper channel pattern, and extending in a third direction intersecting each of the first and the second directions;
a lower source/drain contact below the lower source/drain pattern and connected to the lower source/drain pattern;
an upper source/drain contact above the upper source/drain pattern and connected to the upper source/drain pattern;
a first dummy structure comprising a first dummy pattern extending in the first direction and a first dummy pattern liner layer on a side surface of the first dummy pattern;
a second dummy structure comprising a second dummy pattern extending in the first direction and a second dummy pattern liner layer on a side surface of the second dummy pattern; and
a vertical via penetrating through at least one of the first dummy pattern and the second dummy pattern in the second direction,
wherein the first dummy structure is on a first side of the upper source/drain pattern and the second dummy structure is on a second side of the upper source/drain pattern,
wherein the vertical via is connected to the lower source/drain contact and the upper source/drain contact, and
wherein a side surface of the vertical via is in contact with at least one of the first dummy pattern liner layer and the second dummy liner layer.

18. The semiconductor device of claim 17,
wherein a vertical level of an upper end of the vertical via and a vertical level of respective upper surfaces of the first dummy structure and the second dummy structure are the same, or
wherein the vertical level of the upper end of the vertical via is higher than the vertical level of the respective upper surfaces of the first dummy structure and the second dummy structure.

19. The semiconductor device of claim 17, wherein a distance between a center line of the upper source/drain pattern and a center line of the first dummy structure or a center line of the second dummy structure is the same as a distance between the center line of the upper source/drain pattern and a center line of the vertical via.

20. A semiconductor device comprising:
a lower active region extending in a first direction and comprising:
a plurality of lower channel patterns stacked in a second direction intersecting the first direction; and
a lower source/drain pattern on at least one side of the plurality of lower channel patterns;
an upper active region spaced apart from the lower active region in the second direction and extending in the first direction, the upper active region comprising:
a plurality of upper channel patterns stacked in the second direction; and
an upper source/drain pattern on at least one side of the plurality of upper channel patterns;
a gate electrode surrounding the plurality of lower channel patterns and the plurality of upper channel patterns and extending in a third direction intersecting each of the first and the second directions;
a lower source/drain contact below the lower source/drain pattern and connected to the lower source/drain pattern;
an upper source/drain contact above the upper source/drain pattern and connected to the upper source/drain pattern;
a gate contact on the gate electrode and connected to the gate electrode;
a vertical via on a first side of the upper source/drain pattern and connected to the lower source/drain contact and the upper source/drain contact; and
a dummy structure on a second side of the upper source/drain pattern and comprising:
a dummy pattern extending in the first direction; and
a dummy pattern liner layer on a side surface of the dummy pattern,
wherein a vertical level of an upper end of the vertical via and a vertical level of an upper surface of the dummy structure is the same, or wherein the vertical level of the upper end of the vertical via is higher than the vertical level of the upper surface of the dummy structure,
wherein a vertical level of the upper surface of the dummy structure is lower than a vertical level of an upper surface of the gate electrode, and
wherein a first distance between a center line of the upper source/drain pattern and a center line of the dummy structure is the same as a second distance between the center line of the upper source/drain pattern and a center line of the vertical via.
